(19) United States
(12) Patent Application Publication
(10) Pub. No.: US 2025/0359253 A1
(43) Pub. Date: Nov. 20, 2025

(54) TRANSISTOR INCLUDING DUAL-SIDE POWER AND INNER WRAP-AROUND SILICIDE

(71) Applicant: Taiwan Semiconductor Manufacturing Co., Ltd., Hsinchu (TW)

(72) Inventors: Lo-Heng CHANG, Hsinchu (TW); Huan-Chieh SU, Hsinchu (TW); Cheng-Chi CHUANG, Hsinchu (TW); Chih-Hao WANG, Hsinchu (TW); Chun-Yuan CHEN, Hsinchu (TW)

(73) Assignee: Taiwan Semiconductor Manufacturing Co., Ltd., Hsinchu (TW)

(21) Appl. No.: 19/285,698

(22) Filed: Jul. 30, 2025

Related U.S. Application Data
(63) Continuation of application No. 18/487,920, filed on Oct. 16, 2023.
(60) Provisional application No. 63/499,903, filed on May 3, 2023.

(51) Int. Cl. H10D 64/01; H10D 30/01; H10D 30/43; H10D 30/67; H10D 62/10; H10D 62/13; H10D 84/01; H10D 84/03; H10D 84/83

(52) U.S. Cl. CPC H10D 64/017; H10D 30/014; H10D 30/43; H10D 30/6735; H10D 30/6757; H10D 62/121; H10D 62/151; H10D 64/021; H10D 84/0128; H10D 84/013; H10D 84/0149; H10D 84/038; H10D 84/83

(57) ABSTRACT

An integrated circuit includes a transistor having a plurality of stacked channels. The transistor includes a source/drain region in contact with the channel regions. The transistor includes a silicide in contact with the top of the source/drain region and extending vertically along a sidewall of the silicide. A source/drain contact is in contact with a top of the silicide and extending vertically along a sidewall of the silicide.

### BACKGROUND

There has been a continuous demand for increasing computing power in electronic devices including smart phones, tablets, desktop computers, laptop computers and many other kinds of electronic devices. Integrated circuits provide the computing power for these electronic devices. One way to increase computing power in integrated circuits is to increase the number of transistors and other integrated circuit features that can be included for a given area of semiconductor substrate.

Nanostructure transistors can assist in increasing computing power because the nanostructure transistors can be very small and can have improved functionality over convention transistors. Source and drain regions may be coupled to the nanostructures. It can be difficult to form source and drain regions with desired characteristics.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an integrated circuit, in accordance with some embodiments.

FIG. 2 is a cross-sectional view of an integrated circuit, in accordance with some embodiments.

FIG. 3A-3M are perspective views of an integrated circuit at various stages of processing, in accordance with some embodiments.

FIG. 4 is a perspective view of an integrated circuit, in accordance with some embodiments.

FIG. 5 is a cross-sectional view of an integrated circuit, in accordance with some embodiments.

FIG. 6 is a cross-sectional view of an integrated circuit, in accordance with some embodiments.

FIG. 7 is flow diagram of a method for forming an integrated circuit, in accordance with some embodiments.

### DETAILED DESCRIPTION

In the following description, many thicknesses and materials are described for various layers and structures within an integrated circuit die. Specific dimensions and materials are given by way of example for various embodiments. Those of skill in the art will recognize, in light of the present disclosure, that other dimensions and materials can be used in many cases without departing from the scope of the present disclosure.

The following disclosure provides many different embodiments, or examples, for implementing different features of the described subject matter. Specific examples of components and arrangements are described below to simplify the present description. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following description, certain specific details are set forth in order to provide a thorough understanding of various embodiments of the disclosure. However, one skilled in the art will understand that the disclosure may be practiced without these specific details. In other instances, well-known structures associated with electronic components and fabrication techniques have not been described in detail to avoid unnecessarily obscuring the descriptions of the embodiments of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

The use of ordinals such as first, second and third does not necessarily imply a ranked sense of order, but rather may only distinguish between multiple instances of an act or structure.

Reference throughout this specification to “some embodiments” or “an embodiment” means that a particular feature, structure, or characteristic described in connection with the embodiment is included in at least some embodiments. Thus, the appearances of the phrases “in some embodiments”, “in an embodiment”, or “in some embodiments” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

Embodiments of the present disclosure provide an integrated circuit with nanostructure transistors having improved performance. The nanostructure transistors each have a plurality of stacked channels formed over a substrate. Each nanostructure transistor includes source/drain regions in contact with the channels. A silicide is formed on the source/drain regions. Source/drain metallizations contact the silicide. The silicide extends downward along the lateral surfaces of the source/drain regions, rather than being positioned only on the top of the source/drain regions. Because the silicide extends downward along the source/drain regions, there is a relatively small distance between each nanostructure and the silicide. Furthermore, the source/drain metal can include a portion that extends downward to the silicide from above (front side) and a portion that extends upward to the silicide from a backside conductive via formed in the substrate below.

The configuration of the source/drain regions and the silicide provides several benefits. First, the electrical resistance between the lowest nanostructures and the silicide is greatly reduced with respect to configurations in which the silicide is formed only at the top of the source/drain regions, resulting in reduced power consumption. Second, a large number of channels can be formed without negatively impacting the electrical resistance between lower channels and the silicide. With larger numbers of channels, currents can be conducted through nanostructure transistors without generating excessive amounts of heat. Accordingly, an integrated circuit in accordance with principles of the present disclosure consumes less power and generates less heat. The reduction in heat can also prevent damage to the integrated circuit from overheating. Thus, principles of the present disclosure provide substantial benefits to transistor function and overall integrated circuit function.

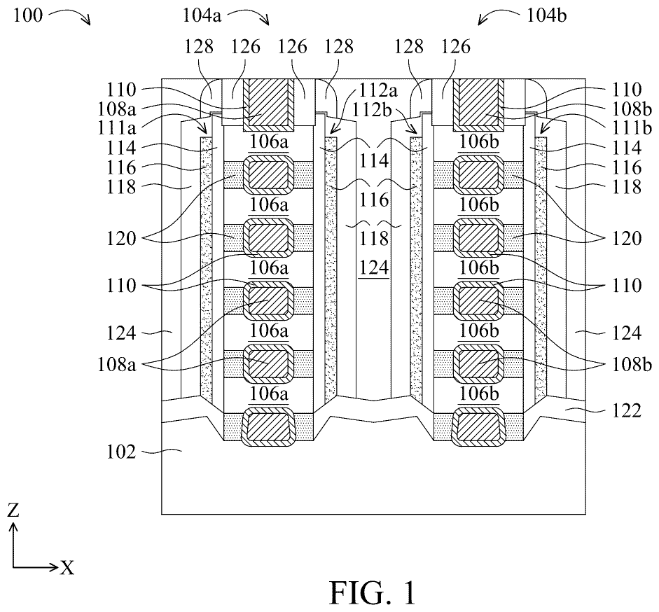

FIG. 1 is a cross-sectional view of an integrated circuit 100, in accordance with some embodiments. The integrated circuit 100 includes a semiconductor substrate 102. The integrated circuit 100 includes a first transistor 104a and the second transistor 104b. Before providing a detailed description of the components of the transistors 104a/104b and other structures of the integrated circuit 100, a brief overview of the general components and basic function of each of the transistors 104a and 104b will be provided.

The transistor 104a includes a plurality of vertically stacked channels 106a. The transistor 104a includes a gate metal 108a corresponding to a gate electrode wrapping around each of the channels 106a. A gate dielectric 110 is positioned between the channels 106a and the gate metal 108a. The transistor 104a includes a source/drain region 111a and a source/drain region 112a. The channels 106a extend in the X direction between the source/drain region 111a and the source/drain region 112a. The source/drain regions 111a and 112a are each made up of a first source/drain layer 114 and a second source/drain layer 116. A silicide 118 lines the vertical sidewall of the source/drain layer 116. Source/drain contacts 124 contact the silicide 118 at the source/drain region 111a and 112a.

The transistor 104b includes a plurality of vertically stacked channels 106b. The transistor 104b includes a gate metal 108b corresponding to a gate electrode wrapping around each of the channels 106b. A gate dielectric 110 is positioned between the channels 106b and the gate metal 108b. The transistor 104b includes a source/drain region 111b and a source/drain region 112b. The channels 106b extend in the X direction between the source/drain region 111b and the source/drain region 112b. The source/drain regions 111b and 112b are each made up of the first source/drain layer 114 and the second source/drain layer 116. The silicide 118 lines the vertical sidewall of the source/drain layer 116. Source/drain contacts 124 contact the silicide 118 at the source/drain region 111b and 112b.

Some reference numbers shown in the Figures include a suffix “a” or “b” to distinguish between the transistors 104a and 104b and their components. In some cases herein, the description may omit the suffixes when given details are not particular to either of the transistors but can correspond to the components of either or both transistors.

The transistors 104 may generally operate in the following manner. A gate voltage may be applied to the gate metal 108 to render the channels 106 conducting or nonconducting. In the example of an N-channel transistor, a gate voltage of ground may turn off the transistor 104, while a gate voltage of VDD may turn on the transistor 104. In the example of a P-channel transistor, a gate voltage of ground may turn on the transistor 104 while a gate voltage of VDD may turn off the transistor 104. If the transistor 104 is turned on and there is a voltage difference between the source/drain region 111 and the source/drain region 112, then a current may flow between the source/drain region 111 and the source/drain region 112 through each of the channels 106. Voltages may be applied to the source/drain regions 111 and 112 via the portions of the source/drain contacts 124 connected to the silicide 118 at the respective source/drain regions 111 and 112.

In some configurations, a silicide is only present on a top surface of the source/drain regions and the source/drain contact is on top of the silicide. In a stacked channel configuration, the lower channels are further from the silicide and source/drain contact than are the upper channels. In general, silicides and source/drain contact metals are more highly conductive than are the semiconductor materials of source/drain regions. Accordingly, in a aforementioned stacked channel transistor, there may be a greater resistance between the lower channels and the source/drain contact metal that there is between the upper channels and the source/drain contact metal. For a given voltage applied between source/drain regions, currents flowing through the lower channels will be smaller than through the upper channels.

The configuration of the source/drain regions 111/112, the silicide 118, and the source/drain contacts 124 of the transistor 104 provide many benefits to the function of the transistor 104 compared to aforementioned transistors. In particular, the distance between the channel 106 and the silicide 118 is substantially the same for each stacked channel 106. Similarly, the distance between the channel 106 and the source/drain contacts 124 is substantially the same for each stacked channel 106. Each channel 106 is separated in the X direction from the silicide 124 by the combined width of the source/drain layers 114 and 116 in the X direction. The result is that each of the channels 106 may conduct substantially the same current. The overall source to drain resistance of the transistor 104 is reduced compared to conventional transistors. Although in FIG. 1 each source/drain region 111 and 112 includes two source/drain layers 114 and 116, in some embodiments the source/drain regions 111 and 112 may each include only a single source/drain layer.

The channels 106 may correspond to semiconductor nanostructures and may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure transistor structure.

The channels 106 may also be termed semiconductor nanosheets, though other types of semiconductor nanostructures can be utilized without departing from the scope of the present disclosure. The channels 106 can include a monocrystalline semiconductor material such as silicon, silicon germanium, or other semiconductor materials. The channels 106 may be an intrinsic semiconductor material or may be a doped semiconductor material. The semiconductor nanostructures may include nanosheets, nanowires, or other types of nanostructures. The channels 106 may have a thickness in the Z direction between 2 nm and 5 nm. The channels 106 may have a width in the X direction between 5 nm and 15 nm. Other materials and dimensions can be utilized for the channels 106 without departing from the scope of the present disclosure.

While FIG. 1 illustrates that each transistor 104 includes five stacked channels 106, in practice, different numbers of stacked channels 106 can be utilized without departing from the scope of the present disclosure. In some embodiments, each transistor 104 may include only a single channel 106.

The gate metal 108 includes one or more conductive materials. The gate metal 108 can include one or more of tungsten, aluminum, titanium, tantalum, copper, gold, or other conductive materials. The gate metal 108 can surround the nanostructures 106 such that each channel 106 extends through the gate metal 108 between the source/drain regions 111/112. The gate metal 108 can include a plurality of gate metal layers including liner layers, work function layers, and gate fill layers. The gate metal 108 includes a top portion above the highest channel 106.

A dielectric layer 126 is positioned adjacent to sidewalls of upper portion of the gate metal. The dielectric layer 126 can include a dielectric material such as silicon oxide, silicon nitride, silicon oxynitride (SiON), SiOCN, SiCN, fluorine-doped silicate glass (FSG), or a low-K dielectric material, or other suitable materials.

Each transistor 104 includes gate sidewall spacers 128 on sidewalls of the dielectric layer 126. The sidewall spacers 128 can include a dielectric material such as silicon oxide, silicon nitride, silicon oxynitride (SiON), SiOCN, SiCN, fluorine-doped silicate glass (FSG), or a low-K dielectric material, or other suitable materials.

A gate dielectric 110 surrounds the nanostructures 106 and acts as a dielectric sheath between the nanostructures 106 and the gate metal 108. Although a single gate dielectric layer 110 is shown, in practice, the gate dielectric layer 110 can include an interfacial gate dielectric layer and a high K gate dielectric layer. The interfacial gate dielectric layer is on the surfaces of the semiconductor nanostructures 122 and on other surfaces. The interfacial gate dielectric layer is deposited on all exposed surfaces of the semiconductor nanostructures 122. The interfacial gate dielectric layer laterally surrounds the semiconductor nanostructures 122. The interfacial gate dielectric layer can include a dielectric material such as silicon oxide, silicon nitride, or other suitable dielectric materials. The interfacial gate dielectric layer can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer can be formed by a thermal oxidation process, a chemical vapor deposition (CVD) process, or an atomic layer deposition (ALD) process. The interfacial gate dielectric layer can have a thickness between 0.5 nm and 2 nm. Other materials, deposition processes, and thicknesses can be utilized for the interfacial gate dielectric layer without departing from the scope of the present disclosure.

The high-K gate dielectric layer has a thickness between 1 nm and 3 nm. The high-K dielectric layer includes one or more layers of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K dielectric layer may be formed by CVD, ALD, or any suitable method. Other thicknesses, deposition processes, and materials can be utilized for the high-K dielectric layer without departing from the scope of the present disclosure.

Each transistor 104 includes inner spacers 120. The inner spacers 120 serve to electrically isolate the channels 106 and the source/drain regions 111/112 from the gate metal 108. The inner spacers 120 can include a low K dielectric material such as SiO2, SiN, SiCN, SiOC, SiOCN, or other suitable dielectric materials.

The first source/drain layer 114 is a thin layer of semiconductor material. The semiconductor material of the first source/drain layer 114 can be the same or different than the semiconductor material of the channels 106. The first source/drain layer 114 can include silicon, silicon germanium, or other suitable semiconductor materials. The first source/drain layer 114 is doped with dopant species. In the case of an N-type transistor, the first source/drain layer 114 can be doped with phosphorus, arsenic, or other suitable dopant species. In the case of a P-type transistor, the first source/drain layer 114 can be doped with boron, aluminum, or other suitable dopant species. The first source/drain layer 114 can have a dopant concentration between 3E19/cm\hat{ }3 and 7E19/cm\hat{ }3.

The first source/drain layer 114 can be formed with an epitaxial growth process from the channels 106. The epitaxial growth process is carefully controlled so that the semiconductor material is grown from the channels 106 and vertically merged to form a vertically extended and conformal first source/drain layer 114. In some embodiments, the first source/drain layer 114 can have a thickness between 2 nm and 6 nm. The source/drain layer 114 extends from the dielectric layer 122 to a level even with or higher than the top surface of the top channel 106. Other thicknesses, materials, and processes can be utilized without departing from the scope of the present disclosure.

The second source/drain layer 116 is a thin layer semiconductor material. The semiconductor material of the second source/drain layer 116 can be the same or different than the semiconductor material of the first source/drain layer 114. The second source/drain layer 116 can include silicon, silicon germanium, or other suitable semiconductor materials. The second source/drain layer 116 is doped with dopant species as described above in relation to the first source/drain layer 114. The second source/drain layer 116 can have a dopant concentration between 1E20/cm\hat{ }3 and 3E20/cm\hat{ }3. In some embodiments, the second source/drain layer 116 has a higher dopant concentration than the source/drain layer 114. The result is that the second source/drain layer 116 is more highly conductive than the first source/drain layer 114.

The second source/drain layer 116 can be formed with an epitaxial growth process from the first source/drain layer 114. In some embodiments, the second source/drain layer 116 can have a thickness between 2 nm and 6 nm. The source/drain layer 116 extends from the dielectric layer 122 to a level even or higher than the top surface of the top channel 106. Other thicknesses, materials, and processes can be utilized without departing from the scope of the present disclosure. Although FIG. 1 illustrates multiple source/drain layers 114/116, in practice, each of the source/drain regions may have a single source/drain layer.

Due to the shape of the dielectric layer 122, the bottom of the source/drain layer 114 may be lower than the bottom of the source/drain layer 116. The top of the source/drain layer 114 may be higher than the top of the source/drain layer 116.

The silicide layer 118 is positioned on the vertical sidewalls of the second source/drain layer 116. The silicide layer 118 wraps around the source/drain regions 111 and 112. Accordingly, the silicide layer 118 can correspond to an inner wraparound silicide. The silicide layer 118 can have a lateral thickness between 2 nm and 8 nm. The silicide 118 acts as an interface between the semiconductor material of the source/drain regions 111/112 and the source/drain contacts 124. The silicide 118 includes both the semiconductor material of the source/drain layer 116 and a metal. As such, the silicide 118 may include titanium silicide, molybdenum silicide, zirconium silicide, Sb silicide, nickel silicide, tungsten silicide, ruthenium silicide, or other types of silicide. The silicide 118 is highly conductive compared to the source/drain regions 111/112. Further details of the silicide 118 will be discussed below.

In some embodiments, the silicide layer 118 has an inverted “L shape”. In particular, for each source/drain region 111/112, the portion of the silicide layer 118 that is above the second source/drain layer 116 has a greater width in the X direction than does the portion of the silicide layer 118 adjacent to the sidewall of the second source/drain layer 116. Accordingly, a portion of the silicide layer 118 is directly on the top surface of the second source/drain layer 116. A portion of the silicide layer 118 is in direct contact with a sidewall of the first source/drain layer 114 at levels higher than a top surface of the source/drain layer 116. A portion of the silicide layer 118 may also be formed on a top surface of the source/drain layer 114. The dielectric layer 128 may be positioned on a top surface of the silicide layer 118.

The source/drain contacts 124 corresponds to metal plugs or conductive vias by which voltages are applied to the source/drain regions 111/112. The source/drain contacts 124 can include tungsten, aluminum, titanium, copper, or other suitable conductive materials. The source/drain contacts 124 are positioned on the vertical sidewalls of the silicide layer 118. The source/drain contacts 124 are in direct contact with the silicide 118. The source/drain contacts 124 may entirely fill lateral gaps between the silicide layer 118 of adjacent transistors. The source/drain contacts 124 apply voltages to the source/drain regions 111/112 via the silicide 118. Similarly, currents flow between the source/drain contacts 124 and the source/drain regions 111/112 via the silicide 118. The source/drain contacts 124 may extend from the dielectric layer 122 to the top of the dielectric layer 126.

The dielectric layer 122 corresponds to a dielectric barrier positioned on top of the substrate 102. The dielectric layer 122 may be positioned directly below the lowest channel 106 and the substrate 104. The dielectric layer 122 may help prevent leakage currents between the substrate and the channels 106 or between the substrate and the source/drain layers 114/116, the silicide layer 118, and the source/drain contacts 124. The dielectric layer 122 may have a thickness between 2 nm and 20 nm. The dielectric layer 122 can include silicon oxide, silicon nitride, silicon oxynitride (SiON), SiOCN, SiCN, fluorine-doped silicate glass (FSG), or other suitable dielectric materials. In some embodiments, the distance between the lowest channel 106 and the highest channel 106 is between 8 nm and 80 nm, though other distances can be utilized without departing from the present disclosure.

In some embodiments, the source/drain contact 124 between the transistors 104a and 104b forms a T-shape. In particular, the source/drain contact 124 is wider between the dielectric layers 128 than between the adjacent portions of the silicide layer 118. Furthermore, the source/drain contact 124 is on a top surface of the silicide layer 118 at the source/drain region 112a. The source/drain contact 124 is also on a top surface of the silicide layer 118 at the source/drain region 112b. The source/drain contact 124 is in contact with a sidewall of the silicide layer 118 of both the source/drain regions 112a and 112b. The bottom of the source/drain contact 124 is substantially even with a bottom of the silicide layer 118.

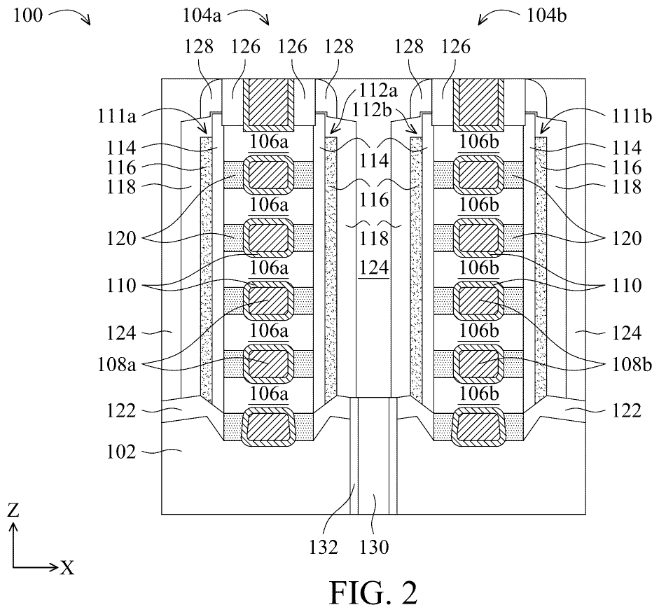

FIG. 2 is a cross-sectional view of an integrated circuit 100, in accordance with some embodiments. The integrated circuit includes a first transistor 104a and a second transistor 104b. The components of the first transistor 104a and the second transistor 104b are substantially similar to those shown and described in relation to FIG. 1, except that a backside conductive via 130 is present in the substrate 102.

The backside conductive via extends from a backside of the integrated circuit 100 through the substrate 102 through the dielectric layer 122 and contacts the central source/drain contact 124 shared by the source/drain region 112a of the transistor 104a and the source/drain region 112b of the transistor 104b. The backside conductive via 130 can include a same material as the source/drain contact 124. Alternatively, the backside conductive via 130 can include a different material than the source/drain contact 124. The backside conductive via 130 can include tungsten, aluminum, titanium, copper, or other suitable conductive materials. The backside conductive via 130 can directly contact the source/drain contact 124 without the silicide layer 118 interposed between.

In some embodiments, the backside conductive via 130 can be utilized as a second power source to provide power to the source/drain regions 112a and 112b. In an example in which the source/drain regions 112a and 112b receive the supply voltage VDD, VDD can be supplied to the backside conductive via 130 as well as to a conductive via or other metal track that connects to the top of the central source/drain contact 124. Ground can also be supplied in the same manner. The backside of the integrated circuit 100 may include one or more layers of metal interconnects by which a voltage can be supplied to the backside conductive via 130. The interface between the backside conductive via 130 and the source/drain contact 124 can be as deep as the lowest channel 106. In some embodiments, the interface between the backside conductive via 130 and the source/drain contact 124 is at a same level as the interface between the silicide layer 118 and the dielectric layer 122. Alternatively, the interface between the source/drain contact 124 and the backside conductive via 130 may be at a level that is higher than the bottom of the silicide layer 118.

In some embodiments, a dielectric layer 132 is positioned between the backside conductive via 130 and the semiconductor substrate 102. The dielectric layer 132 corresponds to a barrier layer that electrically isolates the substrate 102 from the backside conductive via 130. The dielectric layer 132 can include silicon oxide, silicon nitride, silicon oxynitride (SiON), SiOCN, SiCN, fluorine-doped silicate glass (FSG), or other suitable dielectric materials. The dielectric layer 132 may be omitted in examples in which the substrate 102 has been entirely replaced with a dielectric substrate,

In some embodiments, the width of the backside conductive via in the X direction is substantially identical to the width of the source/drain contact 124. In these cases, the trench that is formed in the substrate 102 can be formed wider than the source/drain contact 124 such that when the dielectric layer 132 is deposited, the remaining trench width is the same as the width of the source/drain contact 124. The subsequently deposited conductive via will then have a width that is substantially the same as the width of the backside conductive via 124.

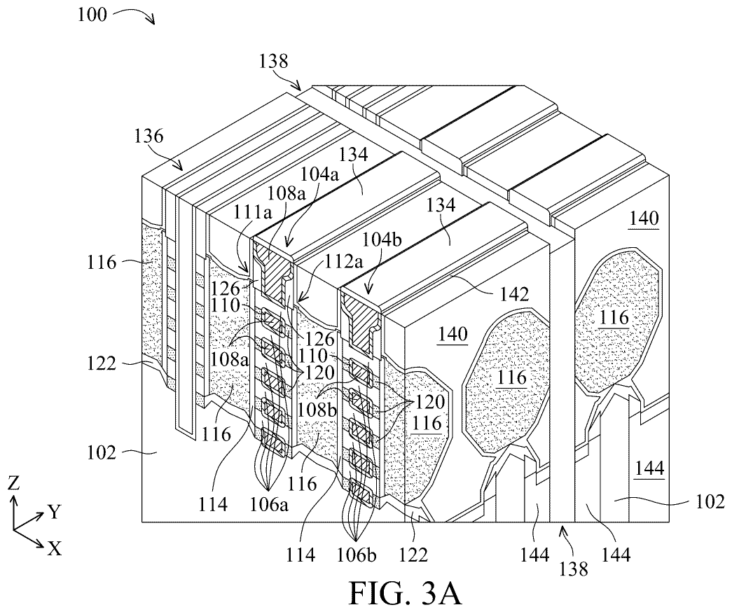

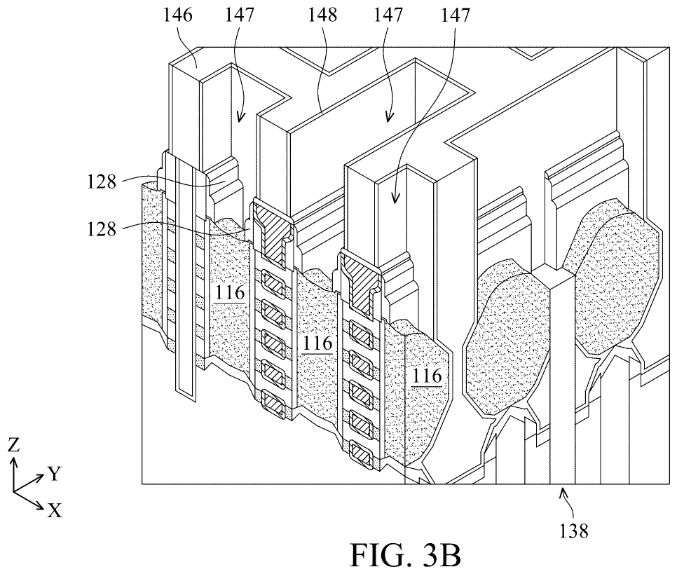

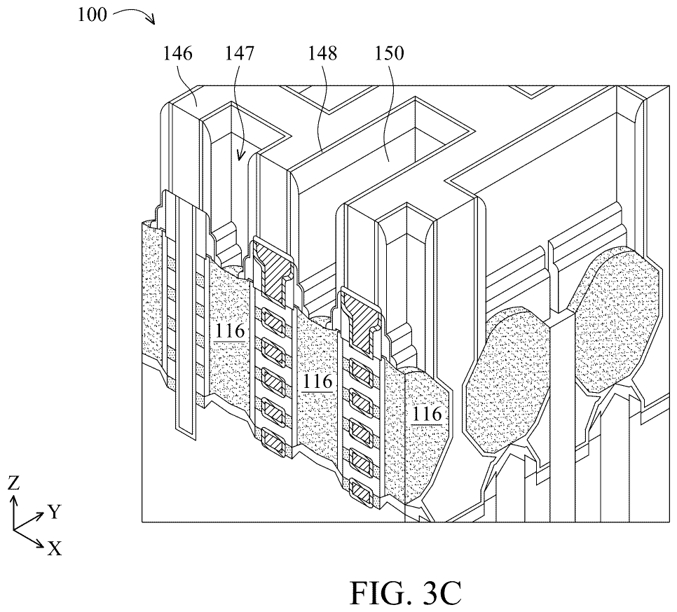

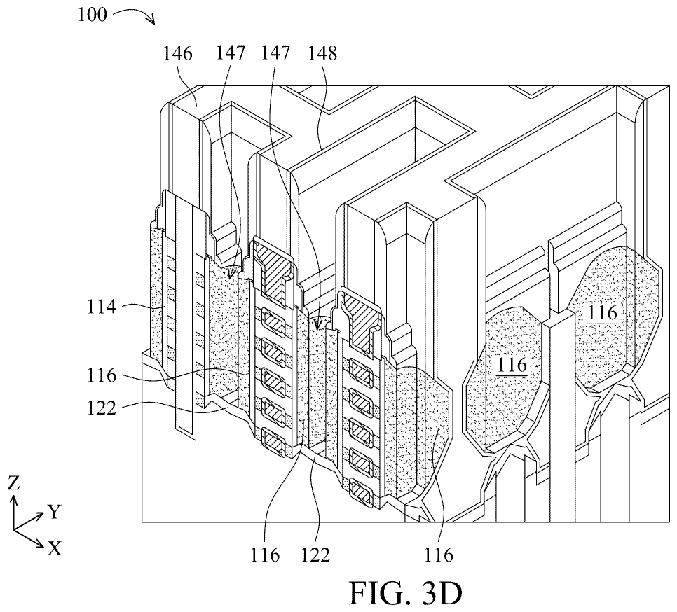

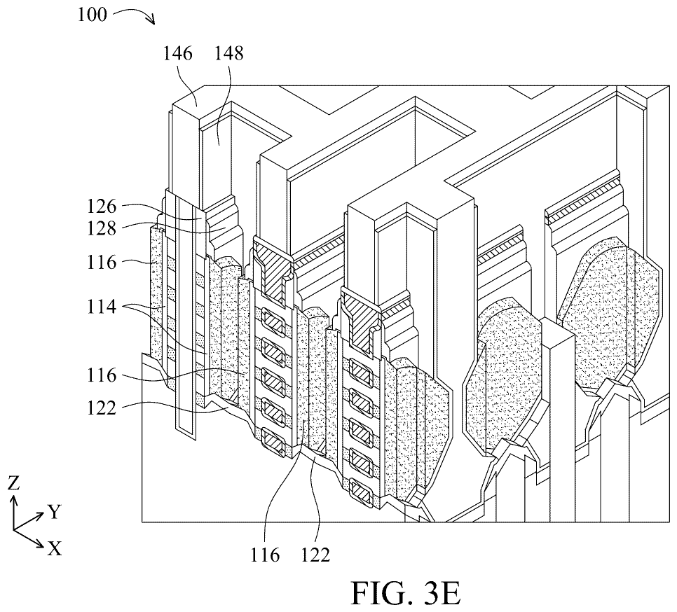

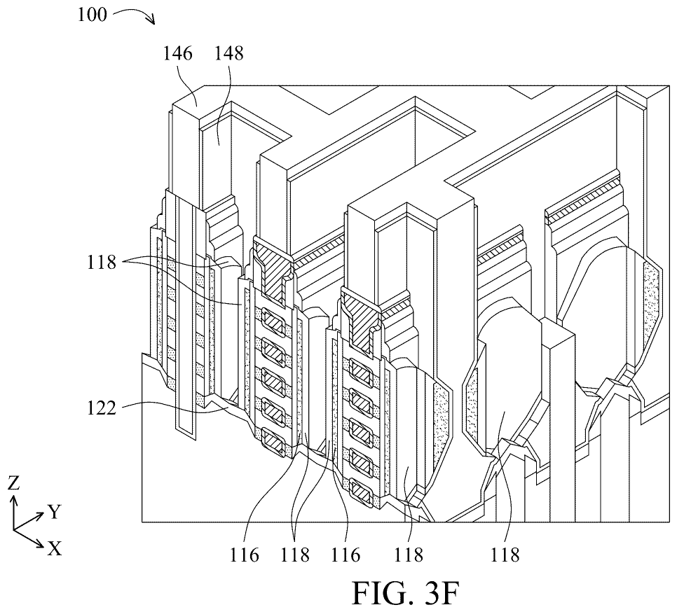

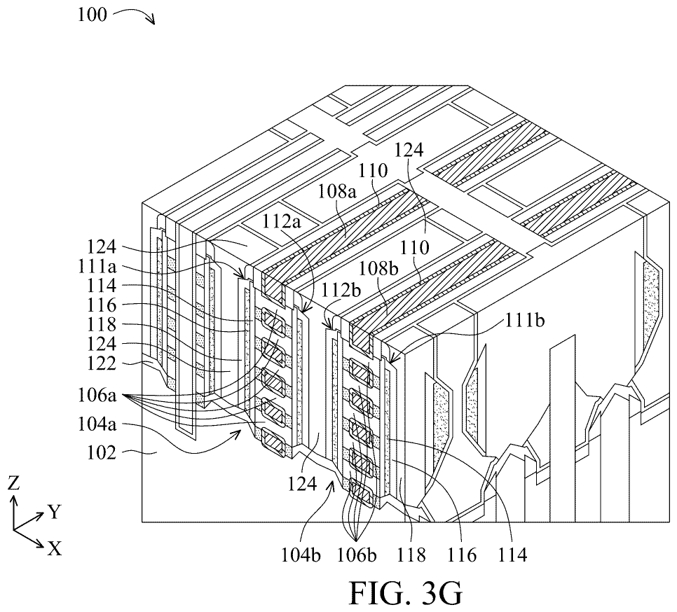

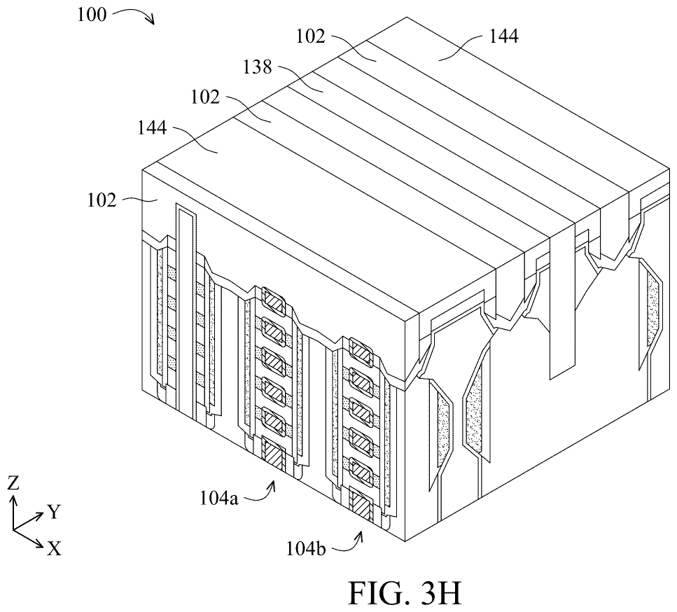

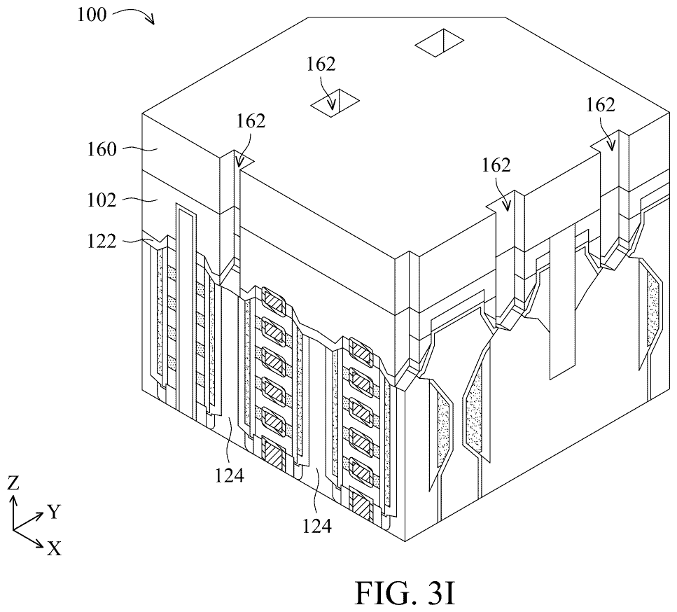

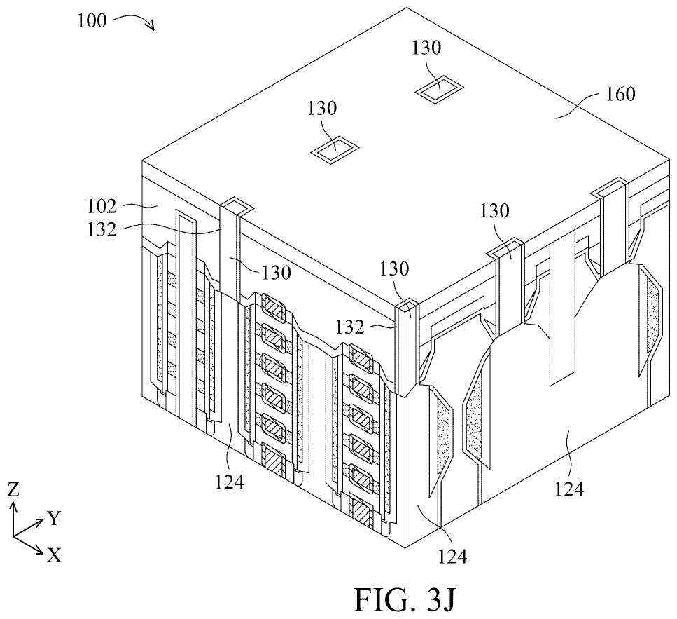

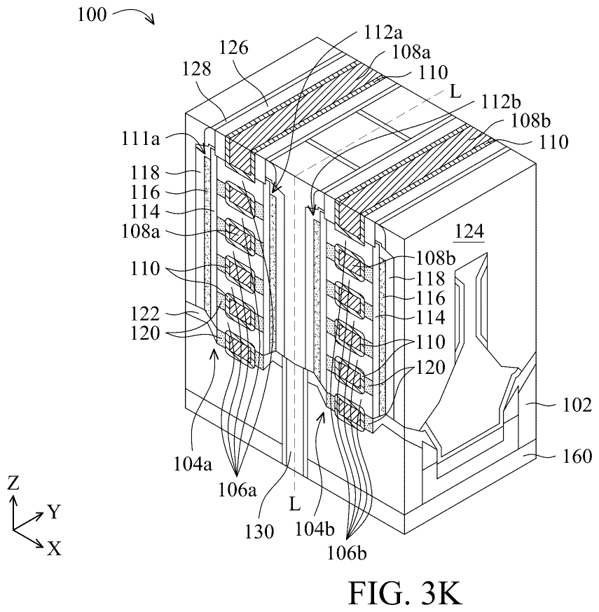

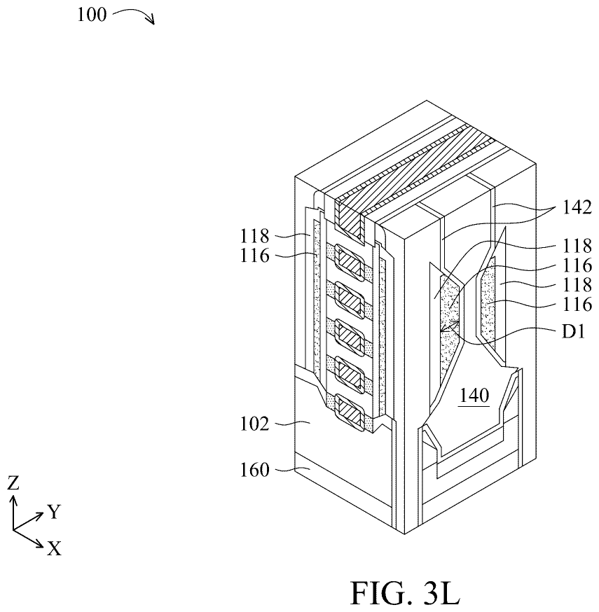

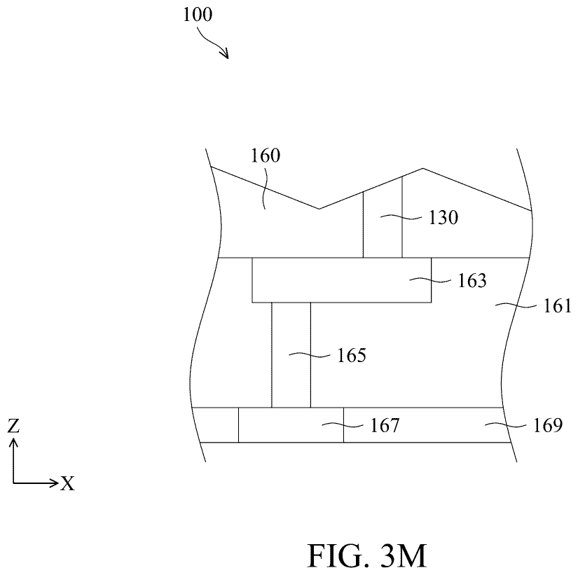

FIGS. 3A-3L are perspective views of an integrated circuit 100 at various stages of processing, according to some embodiments. FIGS. 3A-3L illustrate an exemplary process for producing an integrated circuit that includes nanostructure transistors. FIGS. 3A-3L illustrate how these transistors can be formed in a simple and effective process in accordance with principles of the present disclosure. Other process steps and combinations of process steps can be utilized without departing from the scope of the present disclosure. The transistors can include gate all around transistors, multi-bridge transistors, nanostructure transistors, nanowire transistors, or other types of nanostructure transistors. In the description of FIGS. 3A-3L, structures that are common with those shown and described in relation to FIGS. 1 and 2 can have the same materials, dimensions, and formation processes. Accordingly, the description of some aspects of structure shown in FIGS. 3A-3L may not be repeated.

In FIG. 3A, the channels 106 of the transistors 104 have been formed above the substrate 102. The gate metal 108, the gate dielectric 110, the spacers 120, the dielectric layers 122 and 126, and the source/drain layers 114 and 116 have been formed. At the stage of processing shown in FIG. 3A, the second source/drain layer 116 fills the entirety of the space between adjacent portions of the first source/drain layer 114. As will be set forth in more detail below, portions of the second source/drain layer 116 will subsequently be removed to achieve the shape shown in FIGS. 1 and 2.

In some embodiments, a basic process for forming the structure shown in FIG. 3 a can include forming a stack of channel layers of sacrificial semiconductor layers ultimately stacked over the substrate 102. The stack of channel layers is eventually patterned to form the channels 106. The stack of sacrificial semiconductor layers is eventually removed and the gate metal 108 and the spacers 120 are formed in the place. The dummy gate structure is formed over the stack layers includes a polysilicon dummy gate and gate spacers. Source/drain trenches are then formed in the stacked channel layers and sacrificial semiconductor layers. Recesses are formed in the sacrificial semiconductor layers and the inner spacers 120 are formed in the recesses. The bottom dielectric layer 122 is then formed over the substrate at the bottom of the source/drain trenches. The source/drain layers 114 and 116 are then formed in the source/drain trenches. The etch stop dielectric layer 142 and the interlevel dielectric layer 140 are then formed, as will be described in more detail below. The sacrificial semiconductor layers are then entirely removed and replaced by the gate dielectric 110 and the gate metal 108.

In FIG. 3A, the interlevel dielectric layer 140 has been formed. The interlevel dielectric layer 140 can include one or more of silicon oxide, silicon nitride, silicon oxynitride (SiON), SiOCN, SiCN, fluorine-doped silicate glass (FSG), or other suitable dielectric materials. A dielectric liner layer 142 has also been formed prior to deposition of the interlevel dielectric layer 140. The dielectric liner layer 142 can correspond to an etch stop layer and can include silicon oxide, silicon nitride, silicon oxynitride (SiON), SiOCN, SiCN, fluorine-doped silicate glass (FSG), or other suitable dielectric materials,

In FIG. 3A, gate isolation structures 138 have been formed. The gate isolation structures are utilized to electrically isolate gate metals 108 of transistors that are adjacent to each other in the Y direction. The gate isolation structures 138 can include silicon oxide, silicon nitride, silicon oxynitride (SiON), SiOCN, SiCN, fluorine-doped silicate glass (FSG), or other suitable dielectric materials. The gate isolation structures 138 may also be termed “cut metal gate” (CMG) structures formed in a CMG process that electrically isolates gate structures of adjacent transistors. The cut metal gate process can include utilizing a photolithography process to form trenches through the integrated circuit 100 to remove selected portions of gate structures in order to electrically isolate gate structures of adjacent transistors. The gate isolation structures 138 can be formed in the trenches to isolate gate structures from each other.

In FIG. 3A, dielectric gate structures 136 have been formed. The dielectric gate structures 136 can correspond to isolation structures configured to electrically isolate transistors 104 adjacent to each other in the X direction. The dielectric gate structures 136 are formed in place of the gate metal 108 and entirely cut through the adjacent channels. The dielectric gate structures can include a plurality of dielectric layers including one or more layers of silicon oxide, silicon nitride, silicon oxynitride (SiON), SiOCN, SiCN, fluorine-doped silicate glass (FSG), or other suitable dielectric materials. The dielectric gate structures 136 can be formed at locations at which it is not desired for a functioning transistor to remain, in accordance with a particular circuit schematic or other factors. The dielectric gate structures 136 can be formed in conjunction with a photolithography process in which selected gate structure locations are exposed and trenches are formed to remove the gate metals. One or more dielectric layer can then be deposited in place of the removed gate metals in order to form the dielectric gate structures 136 as shown in FIG. 3A. After formation of the dielectric gate structures 136, a recessing process can be performed to recess the tops of the gate isolation structures 138 relative to the interlevel dielectric layer 140 and the dielectric gate structures.

In FIG. 3A, a dielectric layer 134 has been selectively formed on the top surface of the gate metal 108. The dielectric layer 134 may function as a hard mask for the gate metal 108. The dielectric layer 134 may correspond to a dielectric on metal (DOM) layer. The dielectric layer 134 can include one or more of silicon oxide, silicon nitride, silicon oxynitride (SiON), SiOCN, SiCN, fluorine-doped silicate glass (FSG), or other suitable dielectric materials,

In FIG. 3B, an interlevel dielectric layer 146 has been formed on the interlevel dielectric layer 140. The interlevel dielectric layer 146 can include one or more of silicon oxide, silicon nitride, silicon oxynitride (SiON), SiOCN, SiCN, fluorine-doped silicate glass (FSG), or other suitable dielectric materials. The interlevel dielectric layer 146 can be formed by chemical vapor deposition (CVD), atomic layer deposition (ALD), or physical vapor deposition (PVD). Other materials and processes can be utilized for the interlevel dielectric layer 146 without departing from the scope of the present disclosure.

In FIG. 3B, source/drain contact openings (or trenches) 147 have been formed in the interlevel dielectric layer 146 and the interlevel dielectric layer 142 expose the source/drain layer 116. This can be accomplished by photolithography processes and one or more etching processes.

In FIG. 3B, a dielectric layer 148 has been deposited on sidewalls of the openings 147. The dielectric layer 148 can include one or more of silicon oxide, silicon nitride, silicon oxynitride (SiON), SiOCN, SiCN, fluorine-doped silicate glass (FSG), or other suitable dielectric materials. The dielectric layer 148 can be deposited by CVD, ALD, or PVD. Other materials and deposition processes can be utilized for the dielectric layer 148 without departing from the scope of the present disclosure. The dielectric layer 148 may result in the gate spacers 128. Formation of the openings 147 may also result in etching of the gate isolation structures 138.

In FIG. 3C, a dielectric layer 150 has been conformally deposited on the dielectric layer 148 and on other exposed surfaces. The dielectric layer 150 can include one or more of silicon oxide, silicon nitride, silicon oxynitride (SiON), SiOCN, SiCN, fluorine-doped silicate glass (FSG), or other suitable dielectric materials. In some embodiments, the dielectric layer 150 is silicon oxide and is a same material as the interlevel dielectric layer 146. A subsequent etching process can expose portions of the top surface of the source/drain layer 116. The etching process can include a timed anisotropic etching process that etches selectively in the downward direction such that vertically thinner portions of the dielectric layer 150 are removed while thicker sidewall portions remain, thereby exposing only a portion of the top surface of the source/drain layer 116. Other portions of the source/drain region 116 are protected below the vertically thicker sidewall portions of the dielectric layer 150.

In FIG. 3D, an anisotropic etching process has been performed in the presence of the dielectric layer 148. The etching process is an anisotropic etching process that selectively etches in the downward direction. The etching process is selected to etch the semiconductor material of the second source/drain layer 116. More particularly, the portions of the second source/drain layer 116 that are exposed by the dielectric layer 148 are etched. The result is the trench 147 is extended through the second source/drain layer 116 to expose a portion of the bottom dielectric layer 122. In some embodiments, the second source/drain layer 116 may be entirely removed if the openings 147 are initially wide enough. If the second source/drain layer 116 is entirely removed, the subsequently grown silicide layer 118 (see FIG. 3F) may be formed with the first source/drain layer 114.

In FIG. 3E, the dielectric layer 150 has been removed. The dielectric layer 150 can be removed by an etching process including a wet etch, a dry etch, or other suitable etching processes. A portion of the dielectric layer 148 has also been removed. The top surface of the remaining portion of the second source/drain layer 116 is exposed. The bottom dielectric layer 122 is also exposed.

In FIG. 3F, the silicide layer 118 has been formed on the exposed surfaces of the second source/drain layer 116. The silicide layer 118 can be formed by depositing a metal on the semiconductor material of the second source/drain layer 116. A thermal annealing process can then be performed during which the silicide layer 118 is formed from the metal and the second source/drain layer 116. The result is a conformal silicide layer 118 as described previously. Any excess metal can then be removed in a subsequent etching process.

In FIG. 3G, the source/drain contacts 124 have been formed. The source/drain contacts 124 are in contact with the silicide 118. The source/drain contacts 124 can be formed by depositing a source/drain contact metal via PVD, ALD, or CVD. After deposition of the source/drain contacts 124, a chemical mechanical planarization process (CMP) is performed to expose the gate metal 108.

The stage of processing shown in FIG. 3G may correspond to the stage of processing shown in FIG. 1. In particular, the source/drain contacts 124 have been formed. The bottoms of the source/drain contacts 124 are in contact with the dielectric layer 122, but no backside via has been formed. Though not shown in FIG. 3G, further front side processing can be performed including formation of additional interlevel dielectric layers and layers of metal tracks and conductive vias. Subsequent Figures detail formation of the backside via 130 of FIG. 2.

In FIG. 3H, front side processing is complete and the integrated circuit 100 has been flipped such that the bottom of the substrate 102 now faces upward and the front side now faces downward. In FIG. 3H, a grinding process has been performed to reduce the thickness of backside layers including the substrate 102, the trench isolation regions 104, and the gate isolation structure 138. Alternatively, a CMP process can be performed to reduce the thickness of backside layers in preparation for formation of the backside conductive via 130.

In FIG. 3I, the backside dielectric layer 160 has been formed on the exposed bottom surface of the substrate 102 and on the exposed surfaces of the trench isolation regions 144 and gate isolation structures 138. The dielectric layer 160 can include one or more of silicon oxide, silicon nitride, silicon oxynitride (SiON), SiOCN, SiCN, fluorine-doped silicate glass (FSG), or other suitable dielectric materials. The dielectric layer 160 can be deposited by CVD, ALD, PVD, or other suitable deposition processes.

In FIG. 3I, backside trenches 162 have been formed. The backside trenches 162 can be formed by photolithography processes coupled with one or more etching processes that etched through the backside dielectric layer 160, substrate 102, and the dielectric layer 122 to expose the bottom of selected source/drain contacts 124. The etching processes can include one or more wet etches, dry etches, timed etches, or other types of etching processes.

In FIG. 3J, a dielectric liner layer 132 has been formed on sidewalls of the trenches 162. The dielectric liner layer 132 can include one or more of silicon oxide, silicon nitride, silicon oxynitride (SiON), SiOCN, SiCN, fluorine-doped silicate glass (FSG), or other suitable dielectric materials. The dielectric liner layer 132 can be formed by CVD, ALD, PVD, or other suitable deposition processes.

In FIG. 3J, backside conductive vias 130 have been formed in the trenches 162. The backside conductive vias 130 can be formed by depositing a metal or other conductive material in the trenches 160 via PVD, ALD, CVD, or other suitable deposition processes. The backside conductive vias contact the source/drain contacts 124 without the silicide 118 being interposed. A CMP process can then be performed to remove any excess metal from the dielectric layer 160 and to planarize the dielectric layer 160 and the backside conductive vias 130.

In FIG. 3K, the integrated circuit 100 has been flipped so that the front side faces upward again. The integrated circuit 100 of FIG. 3K corresponds to the stage of processing shown in FIG. 2. FIG. 2 does not illustrate the bottom dielectric layer 160, but the bottom dielectric layer 160 may be present in the integrated circuit 100 of FIG. 2. FIG. 3K illustrates a plurality of channels 106 of each transistor 104, and inner wraparound silicide 118 as described previously, a source/drain contact 124 extending deep between adjacent portions of the silicide layer 118, and a backside conductive via 130 connected to one of the source/drain contacts 124 without any silicide between them. Although not shown in FIG. 3K, additional dielectric layers and metal interconnects can be formed on the backside of the integrated circuit 100 to provide interconnection to the backside conductive via 130 (see FIG. 3M) and to enable provide a power to the source/drain contact 124 from both the backside of the front side. The junction between the backside conductive via 130 and the source/drain contact 124 can be as low as the bottom of the bottom channel 106 or as high as the top of the top channel 106, or between 8 nm and 80 nm below the top of the top channel 106. As set forth previously, additional dielectric layers and layers of metal interconnects and conductive vias can be formed on the front side to provide interconnection to the gates 108 and the source/drain contacts 124.

FIG. 3L corresponds to the stage of processing shown in FIG. 3K, but taken along cut lines L. FIG. 3L illustrates that the remaining source/drain layer 116 has a lateral width in the Y direction with dimension D1. D1 can have a value between 0 nm and 10 nm, though other dimensions can be utilized without departing from the scope of the present disclosure. If the source/drain contact 124 is large enough such that the source/drain layer 116 is etched entirely, then the width in the Y direction is 0 nm. FIG. 3L also illustrates that there is no top side silicide layer 118 because the source/drain contact 124 is the near the bottom sheet, although silicide may be found if the source/drain lateral growth is enough for silicide formation. The silicide layer 118 can be the same for both-type transistors and P-type transistors. Alternatively, the silicide layer 118 can have different profiles for N-type and P-type transistors.

FIG. 3M is a cross-sectional view of a lower portion of the integrated circuit 100 of FIG. 3M, in accordance with some embodiments. FIG. 3M illustrates an example in which additional backside features have been formed. In particular, a metal line 163 has been formed in contact with a bottom of the backside conductive via 130 and with a bottom of the dielectric layer 160. The metal line 163 can include one or more of Al, Cu, Ti, Ta, W, or other suitable conductive materials. A dielectric layer 161 has been formed on the bottom of the dielectric layer 160 covering the metal line 163. The dielectric layer 161 can include one or more of silicon oxide, silicon nitride, silicon oxynitride (SiON), SiOCN, SiCN, fluorine-doped silicate glass (FSG), or other suitable dielectric materials. A conductive via 165 has been formed in the dielectric layer 161 in contact with a bottom of the metal line 163. The conductive via 165 can include W, Ta, Ti, Al, Cu, or other suitable conductive materials. A backside contact pad 167 has been formed in contact with the bottom of the conductive via 165 on a bottom of the dielectric layer 161. The backside contact pad 167 can include Cu, Al, Au, W, Ti, Co, or other suitable conductive material. A passivation layer 169 has been formed on the dielectric layer 161. The contact pad 167 is exposed at the backside of the passivation layer 169. The passivation layer 169 can include silicon oxide, silicon nitride, silicon oxynitride (SiON), SiOCN, SiCN, fluorine-doped silicate glass (FSG), or other suitable dielectric materials. Signals and supply voltages can be provided to the source/drain regions via the contact pad 167 and the various backside interconnection structures such as the conductive via 165, the metal line 163, and the backside conductive via 130.

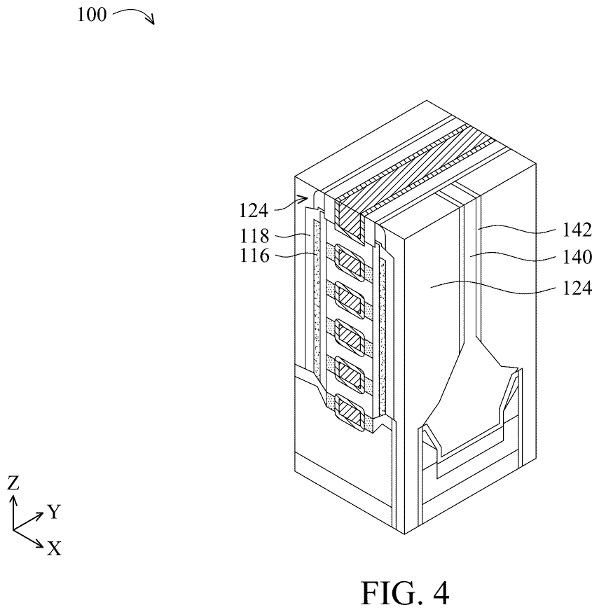

FIG. 4 is a perspective view of an integrated circuit 100, in accordance with some embodiments. The integrated circuit 100 of FIG. 4 is substantially similar to the integrated circuit 100 of FIG. 3L, except that the lateral width in the Y direction of the source/drain layer 116 is zero in the Y direction. This can result from the source/drain layer 116 being etched. This also results in the source/drain contact 124 being wider and abutting the dielectric layers 140 and 142 in locations at which the silicide 118 when otherwise form.

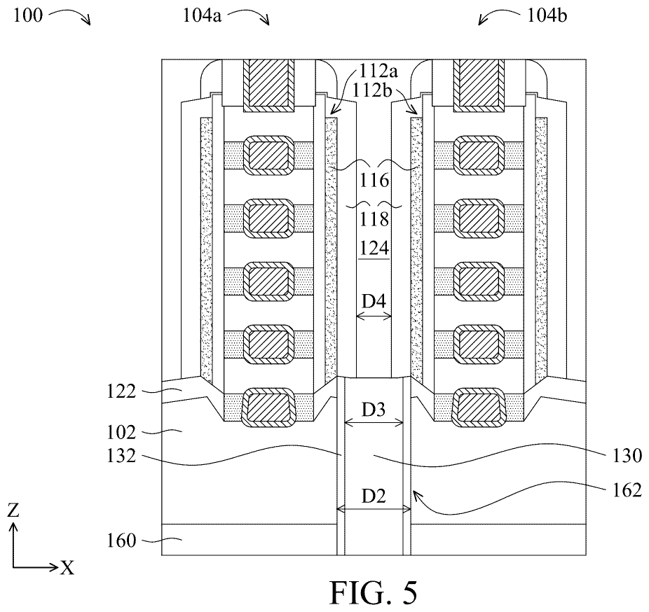

FIG. 5 is a cross-sectional view of an integrated circuit 100, in accordance with some embodiments. The integrated circuit 100 of FIG. 5 is substantially similar to the integrated circuit of FIG. 2, except that the lateral width of the backside conductive via 130 is larger than a lateral width of the portion of the source/drain contact 124 between adjacent portions of the silicide layer 118. In the example of FIG. 5, the backside trench 162 (see FIG. 3I) is formed with a width dimension D2 in the X direction. The width D2 may correspond substantially to the distance between the portion of the second source/drain layer 116 of the source/drain region 112a and the portion of the second source/drain layer 116 of the source/drain region 112b. The dimension D2 may be between 15 nm and 25 nm.

After formation of the trench 162, the dielectric layer 132 is deposited on sidewalls of the substrate 102 and the dielectric layer 160. The result is that after deposition of the backside conductive via 130, the backside conductive via 130 has a width dimension D3 in the X direction. The source/drain contact 124 has a width dimension D4 in the X direction between adjacent portions of the silicide 118. The width dimension D4 is less than the width dimension D3. The backside conductive via 130 abuts the bottom surface of the silicide layer 118. The dimension D3 may be between 11 nm and 21 nm. The dimension D4 may be between 5 nm and 15 nm.

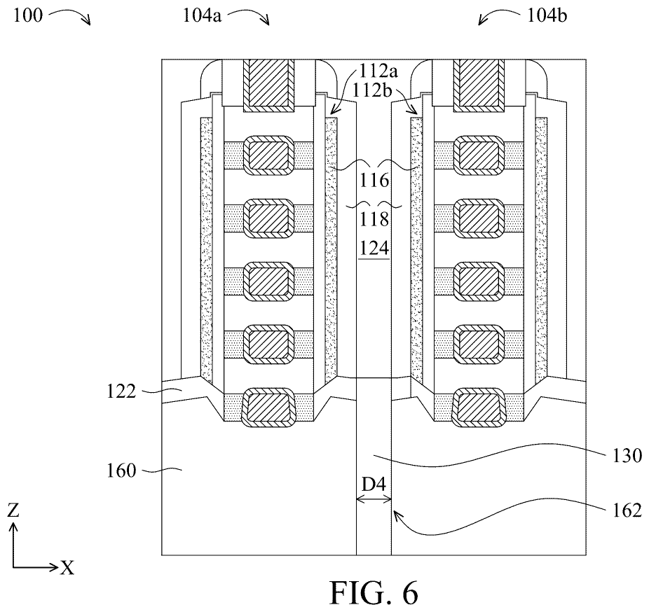

FIG. 6 is a cross-sectional view of an integrated circuit 100, in accordance with some embodiments. The integrated circuit 100 of FIG. 6 is substantially similar to the integrated circuit 100 of FIG. 2, except that the substrate 102 has been replaced entirely with the dielectric layer 160. At the stage of processing shown in FIG. 3H, an etching process may be performed to entirely remove the substrate 102 from the backside of the integrated circuit 100. When the dielectric layer 160 is deposited as shown in FIG. 3I, the dielectric layer 168 will entirely take the place of the substrate 102. The backside trench 162 is then formed. Because the backside trench 162 is not formed in the semiconductor substrate 102, the dielectric barrier layer 132 can be omitted. The backside conductive via 130 can then be deposited in direct contact with the dielectric layer 160.

In the example of FIG. 6, the backside trench 162 has been formed with a same width dimension D4 as the portion of the source/drain contact 124 between adjacent portions of the silicide layer 118. While FIG. 6 illustrates that the backside conductive via 130 abuts the source/drain contact 124 at a level substantially even with the bottom of the silicide layer 118, in practice, the backside trench 162 can be formed such that extends into the source/drain contact 124 (i.e., the etching process etches a portion of the source/drain contact 124). In this case, the interface between the backside conductive via 130 and the source/drain contact 124 will be higher than the bottom of the silicide layer 118. As set forth previously, there may be additional layers of metal interconnects and conductive vias formed on the backside of the integrated circuit 100 to provide connection to the backside conductive via 130 from the backside.

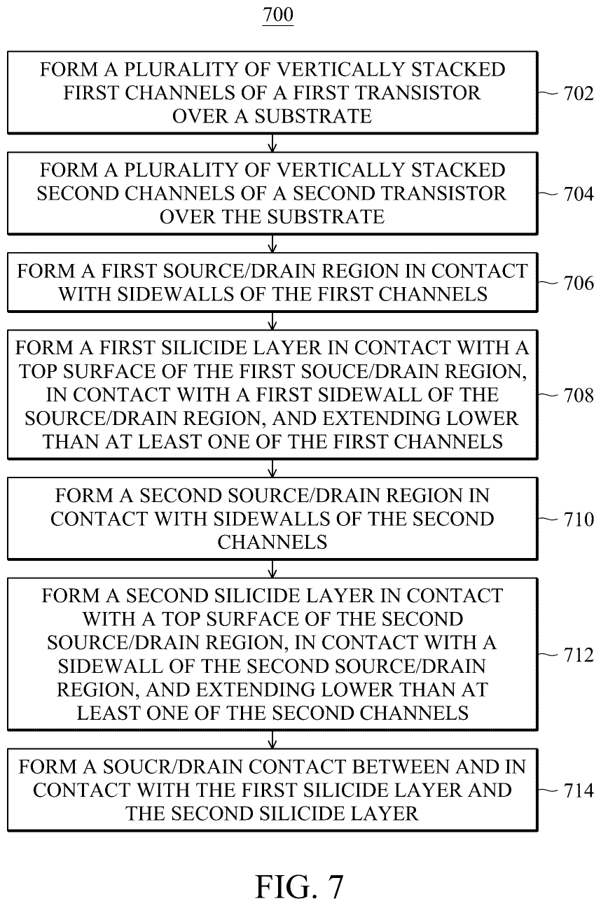

FIG. 7 is a flow diagram of a method 700 for forming an integrated circuit, in accordance with some embodiments. The method 700 can utilize processes, structures, or components described in relation to FIGS. 1-6. At 702, the method 700 includes forming a plurality of vertically stacked first channels of a first transistor over a substrate. One example of first channels are the first channels 106a of FIG. 1. One example of a first transistor is the transistor 104a of FIG. 1. One example of a substrate is the substrate 101 of FIG. 1. At 704, the method 700 includes forming a plurality of vertically stacked second channels of a second transistor over the substrate. One example of second channels are the second channels 106b of FIG. 1. One example of a second transistor is the transistor 104b of FIG. 1. At 706, the method 700 includes forming a first source/drain region in contact with sidewalls of the first channels. One example of a first source/drain region is the source/drain region 112a of FIG. 1. At 708, the method 700 includes forming a first silicide layer in contact with a top surface of the first source/drain region, in contact with a first sidewall of the source/drain region, and extending lower than at least one of the first channels. One example of a first silicide layer is the silicide layer 118 at the source/drain region 112a of FIG. 1. At 710, the method 700 includes forming a second source/drain region in contact with sidewalls of the second channels. One example of a second source/drain region is the source/drain region 112b of FIG. 1. At 712, the method 700 includes forming a second silicide layer in contact with a top surface of the second source/drain region, in contact with a sidewall of the second source/drain region, and extending lower than at least one of the second channels. One example of a second silicide layer is the silicide layer 118 at the source/drain region 112b of FIG. 1. At 714, the method 700 includes forming a source/drain contact between and in contact with the first silicide layer and the second silicide layer. One example of a source/drain contact is the source/drain contact 124 between the source/drain regions 112a and 112b of FIG. 1.

Embodiments of the present disclosure provide an integrated circuit with nanostructure transistors having improved performance. The nanostructure transistors each have a plurality of stacked channels formed over a substrate. Each nanostructure transistor includes source/drain regions in contact with the channels. A silicide is formed on the source/drain regions. Source/drain metallizations contact the silicide. The silicide extends downward along the lateral surfaces of the source/drain regions, rather than being positioned only on the top of the source/drain regions. Because the silicide extends downward along the source/drain regions, there is a relatively small distance between each nanostructure and the silicide. Furthermore, the source/drain metal can include a portion that extends downward to the silicide from above (front side) and a portion that extends upward to the silicide from a backside conductive via formed in the substrate below.

The configuration of the source/drain regions and the silicide provides several benefits. First, the electrical resistance between the lowest nanostructures and the silicide is greatly reduced with respect to configurations in which the silicide is formed only at the top of the source/drain regions, resulting in reduced power consumption. Second, a large number of channels can be formed without negatively impacting the electrical resistance between lower channels and the silicide. With larger numbers of channels, currents can be conducted through nanostructure transistors without generating excessive amounts of heat. Accordingly, an integrated circuit in accordance with principles of the present disclosure consumes less power and generates less heat. The reduction in heat can also prevent damage to the integrated circuit from overheating. Thus, principles of the present disclosure provide substantial benefits to transistor function and overall integrated circuit function.

In some embodiments, an integrated circuit includes a substrate and a transistor. The transistor includes a plurality of channels vertically stacked above the substrate, a source/drain region in contact with the channels, and a silicide layer in contact with a top surface of the source/drain region, in contact with a sidewall of the source/drain region, and extending lower than at least one of the channels. The transistor includes a source/drain contact in contact with a top surface of the silicide layer, in contact with a sidewall of the silicide layer, and extending lower than at least one of the channels.

In some embodiments, an integrated circuit includes a first transistor. The first transistor includes a first source/drain region and a first silicide layer on a top surface and a on sidewall of the first source/drain region. The integrated circuit includes a second transistor. The second transistor includes a second source/drain region and a second silicide layer on a top surface and on a sidewall of the second source/drain region. The integrated circuit includes a source/drain contact in contact with a top surface of the first silicide layer, a sidewall of the first silicide layer, a top surface of the second silicide layer, and a sidewall of the second silicide layer.

In one embodiment, a method includes forming a plurality of vertically stacked first channels of a first transistor over a substrate, forming a plurality of vertically stacked second channels of a second transistor over the substrate, forming a first source/drain region in contact with sidewalls of the first channels, and forming a first silicide layer in contact with a top surface of the first source/drain region, in contact with a first sidewall of the source/drain region, and extending lower than at least one of the first channels. The method includes forming a second source/drain region in contact with sidewalls of the second channels, forming a second silicide layer in contact with a top surface of the second source/drain region, in contact with a sidewall of the second source/drain region, and extending lower than at least one of the second channels, and forming a source/drain contact between and in contact with the first silicide layer and the second silicide layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit comprising:
a semiconductor substrate;
a bottom dielectric layer on the semiconductor substrate;
a transistor including:
a plurality of stacked channels above the substrate and extending in a first lateral direction;
a source/drain region on sidewalls of the channels and on a top surface of the bottom dielectric layer;
a silicide layer extending on a sidewall of the source/drain region and on the top surface of the bottom dielectric layer; and
a source/drain contact in contact with a top surface of the silicide layer, in contact with a sidewall of the silicide layer, and in contact with the top surface of the bottom dielectric layer.

2. The integrated circuit of claim 1, wherein the source/drain region has a first thickness in the first lateral direction, wherein the silicide layer has a second thickness in the lateral direction greater than or equal to the first thickness.

3. The integrated circuit of claim 1, wherein the silicide layer is in contact with a top surface of the source/drain region.

4. The integrated circuit of claim 1, wherein the silicide layer has an inverted “L” shape.

5. The integrated circuit of claim 1, wherein a bottom of the silicide layer is substantially even with a bottom of the source/drain contact.

6. The integrated circuit of claim 1, wherein the transistor includes a plurality of dielectric inner spacers interleaved with the channels, wherein the source/drain region includes:
a first source/drain layer in contact with sidewalls of the channels and with sidewalls of the dielectric inner spacers; and
a second source/drain layer in contact with a sidewall of the first source/drain layer, the first source/drain layer being positioned between the channels and the second source/drain layer.

7. The integrated circuit of claim 6, wherein the first source/drain layer has a lower dopant concentration than the second source/drain layer.

8. The integrated circuit of claim 6, wherein the first source/drain layer extends higher than a top of the second source/drain layer and lower than a bottom of the second source/drain layer.

9. The integrated circuit of claim 8, wherein a bottom of the silicide layer is substantially even with a bottom of the second source/drain layer and with a bottom of the source/drain contact.

10. The integrated circuit of claim 7, wherein the silicide layer is in contact with a sidewall of the first source/drain layer above the second source/drain layer.

11. The integrated circuit of claim 1, comprising a backside conductive via extending through the substrate and directly contacting a bottom of the source/drain contact.

12. The integrated circuit of claim 11, wherein the backside conductive via has a same width in the first lateral direction as the source/drain contact.

13. The integrated circuit of claim 11, wherein the backside conductive via has a larger width in the first lateral direction than the source/drain contact and directly contacts a bottom of the silicide layer.

14. An integrated circuit, comprising:
a semiconductor substrate;
a bottom dielectric layer on the semiconductor substrate;
a first transistor including:
a first source/drain region; and
a first silicide layer on a sidewall of the first source/drain region and on a top surface of the bottom dielectric layer;
a second transistor including:
a second source/drain region; and
a second silicide layer on a sidewall of the second source/drain region and on a top surface of the bottom dielectric layer; and
a source/drain contact in contact with the first silicide layer, the second silicide layer, and the bottom dielectric layer.

15. The integrated circuit of claim 13, wherein the source/drain contact has a T shape.

16. The integrated circuit of claim 15, wherein the bottom dielectric layer is in contact with a bottom of the source/drain contact.

17. The integrated circuit of claim 13, further comprising a backside conductive via extending through a substrate below the first and second transistors and contacting a bottom of the source/drain contact.

18. A method, comprising:
forming a plurality of vertically stacked first channels of a first transistor over a semiconductor substrate;
forming a plurality of vertically stacked second channels of a second transistor over the semiconductor substrate;
forming a bottom dielectric layer on the semiconductor substrate;
forming a first source/drain region in contact with sidewalls of the first channels and the bottom dielectric layer;
forming a first silicide layer in contact with the first source/drain region and the bottom dielectric layer;
forming a second source/drain region in contact with sidewalls of the second channels;
forming a second silicide layer in contact with the second source/drain region and the bottom dielectric layer;
forming a source/drain contact between and in contact with the first silicide layer, the second silicide layer, and the bottom dielectric.

19. The method of claim 18, wherein the source/drain contact has a T-shape.

20. The method of claim 18, comprising forming a backside conductive via in the substrate and contacting a bottom of the source/drain contact.
